(19) United States
(12) Patent Application Publication
(10) Pub. No.: US 2015/0333619 A1
(43) Pub. Date: Nov. 19, 2015

(54) Enabling nearly constant rate of change of discharge current in an inductor discharging circuit by optimizing a snubber resistor value

(71) Applicant: Lawrence A. Leske, Las Vegas, NV (US)

(72) Inventor: Lawrence A. Leske, Las Vegas, NV (US)

(21) Appl. No.: 14/120,274

(22) Filed: May 13, 2014

(51) Int. Cl. H02M 1/34; G01R 27/02

(52) U.S. Cl. CPC H02M 1/34; G01R 27/02; H02M 2001/348

(57) ABSTRACT

Protecting the switching part of an inductive discharge circuit typically incorporates a power output capacitor and a snubber circuit, incorporating a resistor to dissipate the output coil's stored inductive energy. To effect a nearly constant rate of change of the output inductor's current during the time the snubber circuit is active requires transforming the latter by establishing an optimal snubber resistor value. This invention discloses both a device and method for optimizing a snubber resistor value to enable nearly constant rate of change of discharge current in an inductor discharging circuit.

### BACKGROUND OF THE INVENTION

A circuit with a capacitor discharging through an inductor often requires a snubber circuit to prevent accidental damage to that circuit's individual components from those discharges; this hazard primarily arising from over-voltage from the inductor during the power-off time of the output switch. To the extent that the intent of the circuit is to effect maximum inductive power transfer, then the circuit's output current slew rate must remain constant for as long as practical. This arises from the fact that the energy transfer equals the rate of change of current in the inductor multiplied by the total time of the current's flow through the inductor. To avoid dissipating the current or shorting the time stability, the resistance value of the resistor in the snubber must be such as to maintain the rate of change of current for as long as possible during the off time of the switch.

### DESCRIPTION OF THE DRAWINGS

FIG. 1 is a drawing of a device for selecting a snubber resistor value to enable nearly constant rate of change of discharge current for an inductor discharging circuit. The user plugs in (or otherwise connects, which meaning hereinafter is ascribed to ‘plugs in’) an intended output inductor to an inductance-measuring element (1), and an intended output capacitor to a capacitance-measuring element (2), and uses these respective measuring elements to obtain respective real-world values (inductance and capacitance measurements) for that inductor and capacitor. These real-world values are fed to a first processing element (3) that determines and sets as a root-determined-value the positive square root of the quotient of the inductance obtained by the inductance-measuring element (1) divided by the capacitance obtained by the capacitance-measuring element (2), thereby establishing as a first real-world constraint for the snubber resistance value, an optimal and goal resistance value. The user also plugs in each and all of an intended output inductor and all its connected and intended output wiring and any connector(s), to at least one resistance-measuring element. In the preferred embodiment, this occurs together rather than separately, though it is shown with separate resistance-measuring elements respectively as (4), (5) and (6). The user uses the resistance-measuring element to obtain a respective actual and measured resistance from each of the intended output inductor (4), and its output wiring (5) and connector(s) (6), and it feeds their respective actual and measured resistances to a second processing element (7) that receives from the resistance-measuring element the actual and measured resistance of each of the intended output inductor, its connected and intended output wiring and any connector(s), and by summing these resistances determines and sets as a sum-determined value an actual and total in-circuit resistance as a second real-world constraint for the snubber resistance value. After all of the measurements are taken and each of the optimal and goal resistance value and the actual and total in-circuit resistance have been determined, both the optimal and goal resistance value and the actual and total in-circuit resistance are fed to means for subtracting the latter from the former (so from the optimal and goal resistance value the actual and total in-circuit resistance is subtracted) (8), thereby determining, establishing, and any of storing and displaying on a display element (9), as a specific and actual design constraint, realized from actual and measured real-world values and constraints, what the optimal actual snubber resistor value should be for the inductor discharging circuit.

FIG. 2 is a drawing of a capacitor-charging circuit that uses AC power supply source (10) with a rectifier circuit (11), showing the limiting resistor (12) placed in series between the source (10) and the capacitor to be charged (13). The circuit's load—such as that of a pulsed electromagnetic field device—is symbolized by the output inductor (14), and spark gaps (15), which will discharge the capacitors when the capacitor charge is sufficient. The snubber consists of a diode (16) in series with the selected resistor (17), this circuit in parallel with the output inductor. The device and process described in this invention are used to determine, from the values of the capacitor (13), inductor (14), and wiring and connectors (not separately numbered), what the actual snubber resistor value for the selected resistor (17) should be.

FIG. 3 is a drawing of the same capacitor-charging circuit that uses a non-linear direct power supply with an internal bridge rectifier (21); again the limiting resistor (22) is placed in series between the source (23) and the capacitor to be charged (24); and again the circuit's load is symbolized by the inductor (25), and the controlled rectifier switch (26). In this case the protective snubber resistor (27) functions to protect the circuit elements when the inductor (25) is generating a reverse voltage, at the end of its discharge cycle, which will forward bias the diode (28). Hence it will continue to allow current to flow through the output inductor at a rate determined by the value of the snubber resistor (27), the inductor's (25) inherent resistance and the resistance of the wiring and connectors, if any. The device and process described in this invention are used to determine, from the values of the capacitor (24), inductor (25), and wiring and connectors (again not separately numbered), what the actual snubber resistor value for the protective snubber resistor (27) should be.

FIG. 4 is a drawing of the steps of the method in a preferred sequence of operation. First is determining the output capacitance value (31); second is determining the output inductance value (32); third is determining the output inductor's resistance (33); fourth is determining the output wiring and connector resistance (34). Together these allow calculation of the total output snubber resistor circuit value. Fifth determine the optimal output resistance by taking the square root of the quotient of the output inductance divided by the output capacitance (35). Sixth, subtract the total of the output inductor's resistance and the output wiring and connector resistance, from the optimal output resistance (36). This is then the determined value for the snubber resistor in this circuit.

FIG. 5 is a drawing of a further embodiment of the device which incorporates error-detecting and correcting means to protect against common, and cross-cultural, circuit-design errors. In addition to the elements and operations detailed in FIG. 1, means are incorporated to validate and as necessary establish a standard measurement scheme for all measurements and calculations depending thereupon. When the user measures (or enters) a value both its amplitude (e.g. ‘10’) as an operand and the operand's mensuration unit (e.g. ‘Ohms’) are entered. Before a calculation is effected, a comparative check is run on the mensuration units of the operands (10, 12). If a difference is detected between the mensuration units of two operands, then a cross-check on the differentiated pair of mensuration units is run (20) and a transformation, from a standardized table of comparatives (22) is effected on at least one operand to standardize both mensuration units to a common and standardized unit, after which the calculation is allowed to proceed using the replacement common and standardized mensuration unit for all operands, corrected or as originally measured. If no comparative unit is found then a specific error message identifying the differentiation between mensuration units is displayed and the calculation does not go forward (not shown in this Figure).

### SUMMARY OF THE INVENTION

To enable nearly constant rate of change of discharge current in an inductor discharging circuit, which is enabling the switch off snubber current to continue at the same rate as the switch on, one optimizes the value of the desired snubber resistance, and thus the choice of snubber resistor, as follows:

First, determine the output power capacitor's capacitance value.

Second, determine the output inductor's inductance value.

Third, establish the optimal snubber resistor value by taking the positive square root of the quotient of the inductance value from the 2^{nd} step divided by the capacitance value from the 1^{st} step.

Fourth, determine the output inductor's resistance value.

Fifth, determine the output wiring and connector total resistance value.

Sixth, total the 4^{th} and 5^{th} step resistance values to determine the actual in-circuit resistance value.

Finally, subtract the sixth step's actual in-circuit resistance value (the total of resistance values from the 3^{rd}, 4^{th} and 5^{th} steps) from the third step optimal snubber resistor value, to determine the actual, optimal snubber resistance value for the snubber resistor.

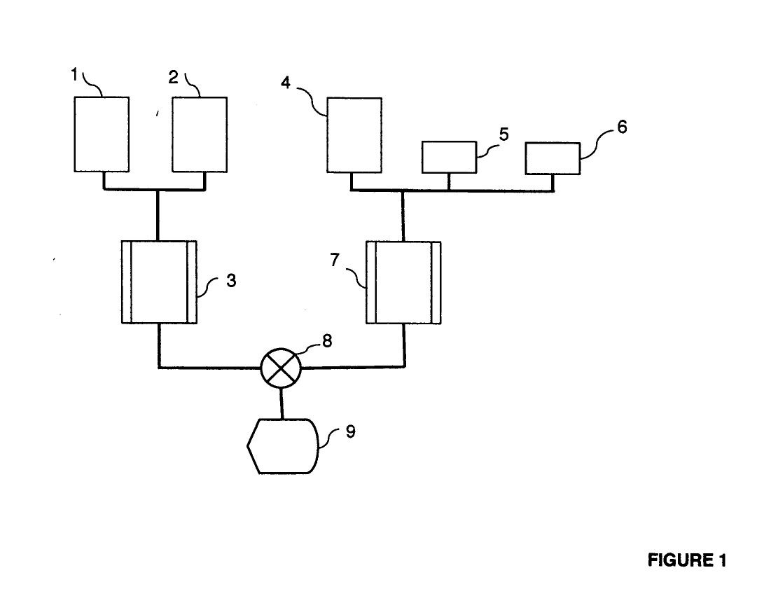

A device which enables the separable measurement of the first, second, fourth, and fifth steps above, and the processing and calculations described in the third, sixth, and seventh steps, and the display of the result, upon the user's activation and fitting to it the requisite units to be measured (or in an alternative embodiment, entering one or more said values after they have been measured separately), and displays the measured and actual, optimal snubber resistance value, is shown and described above as FIG. 1.

### DETAILED DESCRIPTION OF THE INVENTION

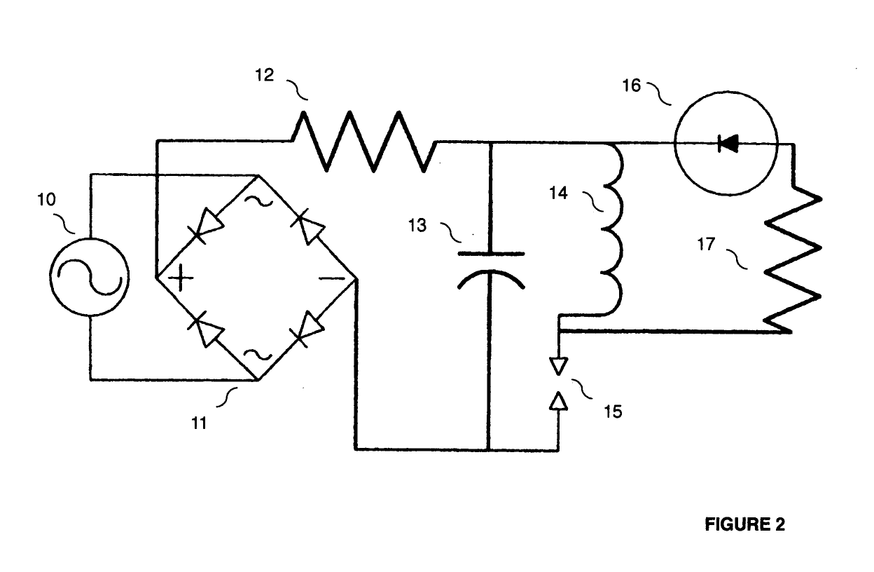

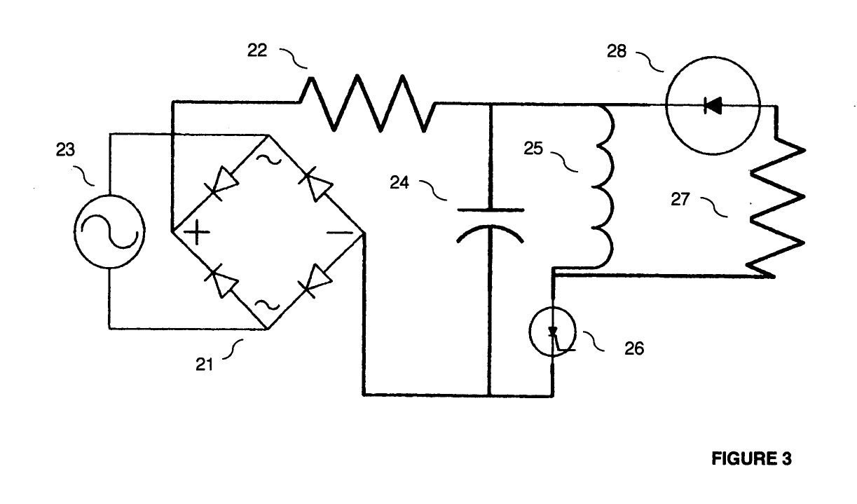

There are at least two general means to discharge a capacitor through an inductor. Either one uses a spark gap if the output voltage is high enough (FIG. 2), or a solid state switch (FIG. 3). Protection for the output capacitor and the solid state switch is necessary. There are many forms possible for this protection, most are passive dissipative circuits which prevent over voltage returning to the switch or capacitor, and are usually called snubbers. In order to provide the simplest means of protection with the added requirement of maintaining the same rate of change of current during the snubber operation, when the diode is forward biased, it is necessary to accurately chose the resistance of the snubber element.

Failing to account for the real-world fact that every element in an electrical circuit requires in-circuit wiring and connections, which each bring their particular resistance, is a common and general error for most circuit designs and a great many digital simulators which simplify away or ignore such ‘complicating frictions’. Thus optimizing the actual, optimal snubber resistor value requires taking into account all of the circuit elements (including the in-circuit wiring and connectors) involved during the snubber circuit's operation.

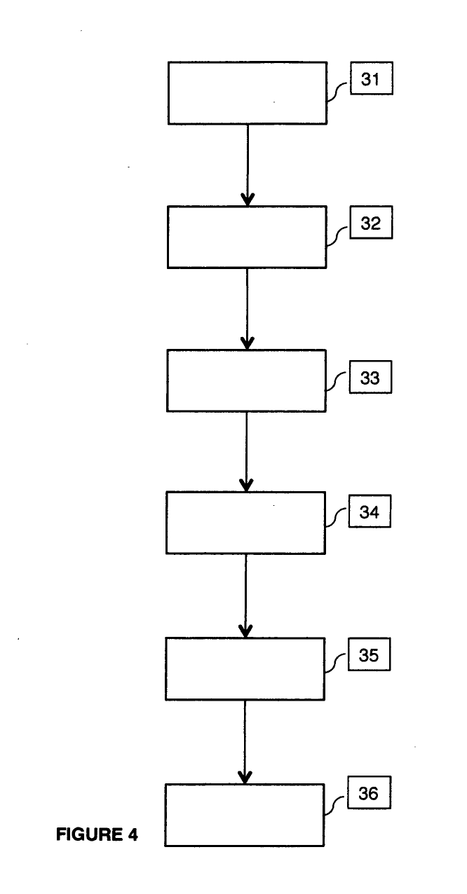

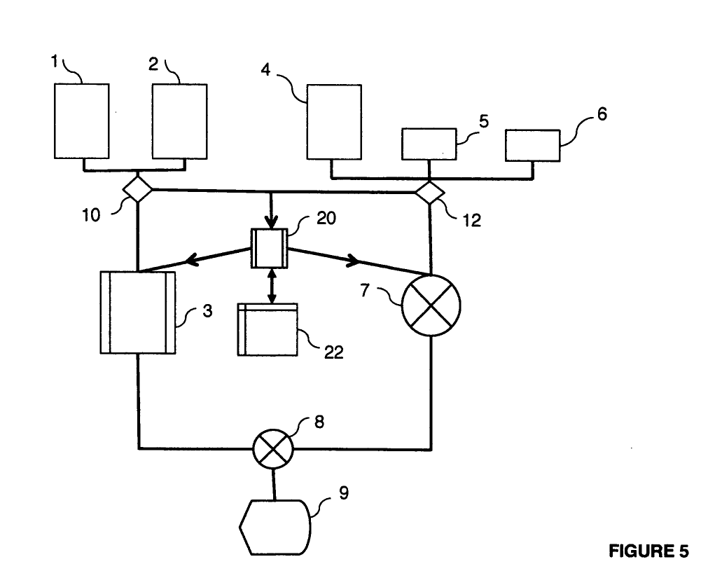

In order to make the optimal selection of the snubber resistor, which is to say to know what the actual, optimal snubber resistor value should be, all of the following measurements, in a preferred embodiment are made first: 1) Power capacitor capacitance; 2) Output inductor inductance; 3) Output inductor resistance; and, 4) Resistance of wiring and connectors to the output inductor (the in-circuit resistance). The order of measurements is not critical beyond ensuring that all required for a calculation, are made before the calculation itself is made. (Thus avoiding errors of having undetermined or ‘null’ operands.) (FIG. 4) As a further improvement, the units of mensuration are specified explicitly and checked for equivalence (FIG. 5), which in yet a further embodiment includes setting the correct scientific notation for values having highly-differentiated powers of 10.

After all of the measurements have been made, determine the optimal total resistance (‘OTR’) by finding the positive square root of the quotient of the inductance (2) divided by the capacitance (1). (This calculation can be expressed as OTR=|SqRt[Inductance/Capacitance]|.) For example if the capacitance is 70 microfarads, and the inductance is 75 micro-henries, then the division would be of 75/70, and the positive square root of the quotient of 75/70 is 1.04 Ohms (1.035098339; rounded to 2 places). Consequently, continuing this example, if the total of the resistance of the inductor with its wiring and connector's resistance is 0.4 Ohms, the optimal snubber resistance value is then (1.04−0.4 Ohms)=0.64 Ohms.

In an alternative embodiment of this invention the first processing element, second processing element, and means for subtracting from the optimal and goal resistance value the actual and total in-circuit resistance, further comprise a single arithmetic processing element capable of each of addition, division, root extraction, and subtraction; memory for the operand values; memory for the result value; control and timing process circuitry; and connections to the input and output feeds for the measurement, constraint, and result values effected by the operation of the arithmetic processing element, to minimize the necessary circuitry; and, as necessary, input and output devices and displays to allow the user to effect and track the measurements and constraint determinations.

A device which allows the user to plug in each and all of the intended output inductor, the intended output capacitor, the intended output inductor, and all of the output wiring and connector(s), which sends the measurements from the first and second to a processing element that divides the first by the second and then finds the square root of that division; and sends the measurements from the third, fourth and fifth to a processing element to be subtracted from the square root of that division. In a preferred embodiment the square root is produced by a first processing element and the in-circuit resistance is summed by a second processing element, before the in-circuit resistance is subtracted from the square root of the division; yet in an alternative embodiment from the square root can be subtracted in any non-duplicative order all of the third, fourth and fifth values (the in-circuit resistance), thereby determining the actual, optimal snubber resistor value.

In yet a further embodiment the display (9) shows both the calculated value, and the mensuration unit thereof (e.g. ‘0.4’ and ‘Ohms’).

In yet a further embodiment each measuring element is connected to a display that shows both the measured value and the unit of measurement (‘mensuration unit’) thereof; with this display either being specific and particular to that measuring element, or shared by and displaying the last measured (or calculated) value.

In yet a further embodiment the device and method allow the entry of a predetermined actual, and optimal snubber resistor value from which a selected specific value for another, user-selected element of the inductive discharge circuit may be identified (as opposed to being measured) through solving for that value as an unknown. Thus if the actual, optimal snubber resistor value were predetermined (perhaps through economic cost preference for a given resistor on the market) to be 0.64 Ohms, and the inductance and capacitance values were also as in the first example above, and the inductor's resistance value was 0.1 Ohms, then the solved value for the in-circuit resistance from the wiring and connectors would be 0.3 Ohms (as the total for inductor's resistance, and wiring and connectors resistance, has already been set as being 0.4 Ohms, and 0.4−0.1=0.3 Ohms). A device and method for this ‘open element’ resolution will incorporate any of memory and processing elements appropriate to the back-transformative calculations and linkage to the display (9) for the back-solved value.

In yet a further embodiment when more than one element has an undetermined value the device has a graphical display which can show as a curve the optimal values over the range(s) of undetermined values for the elements involved. A device and method for this ‘open element’ resolution will incorporate any of memory and processing elements appropriate to the back-transformative calculations and linkage to the display (9) for the back-solved value pairings.

In yet a further embodiment when the snubber resistor value is already fixed, the method will comprise adding to the snubber resistor value the total circuit resistance obtained by summing the measured resistances to obtain the optimal snubber resistor value; then for the output inductor's inductance and output capacitor's capacitance, calculating respective paired values of inductance and capacitance which will, for their calculated positive square root and division, match the optimal snubber resistor value; and displaying, for any selected value of either inductance or capacitance, the matching other value.

The process which is incorporated into and effected through the device described above is as follows: measure all of the elements which will be in the inductive discharge circuit, namely:
determine the output power capacitor's capacitance;
determine the output inductor's inductance;
determine the output inductor's resistance; and,
determine the output wiring and connector(s) combined resistance which comprise the in-circuit resistance;
   then establish the optimal snubber resistor value by taking the positive square root of the quotient of the inductance divided by the capacitance;
   also total the output inductor's, output wiring and connector resistances, thus establishing the in-circuit resistance; and,
   finally subtract the in-circuit resistance optimal snubber resistor value to determine the actual, optimal snubber resistance value.

### General Considerations as to the Scope of Invention

The scope of this invention includes any combination of the elements, or steps, from the prior art, with any of the different embodiments disclosed in this specification; and is not limited to the specifics of any, or any combination, of the alternative embodiments mentioned above. Each claim stated herein should be read as including those elements, or steps, which are not necessary to the invention yet are in the prior art and are necessary to the overall function of that particular claim; and should be read as including, to the maximum extent permissible by law, known functional equivalents, whether expressly or implicitly contained within the prior art, to the elements, or steps, disclosed in the specification, even though those functional equivalents are not exhaustively detailed herein or individually claimed below due to the legal policy preferring limiting the number of claims, and the legal policy to negate any requirement for combinatorial explosion of overly-detailed description and claiming of known and foreseeable alternatives.

While this invention has been described with reference to illustrative embodiments, this description is not to be construed in a limiting sense. Various modifications and combinations of the illustrative embodiments, differing order of the sub-elements or sub-steps (including parallel and partial processing for one or more operations thereof), as well as other embodiments of the invention, will be apparent to those skilled in the relevant arts, upon referencing this specification. This disclosure is intended to encompass any combination of the specifics described here and such modifications or embodiments. Furthermore, the scope of this invention includes any combination of the subordinate elements from the different embodiments disclosed in this specification, and is not limited to the specifics of the preferred embodiment or any of the alternative embodiments mentioned above. Individual configurations and embodiments of this invention may contain all, or less than all, of those disclosed in the specification, but in no case less than that which exceeds the prior art, according to the needs and desires of that user seeking a commercially-advantageous, particular cost-benefit target, compromise embodiment of the invention disclosed herein. Accordingly, it is intended that the appended claims are interpreted as covering all alterations and modifications as fall within the true spirit and scope of the invention in light of the prior art.

Additionally, although claims have been formulated in this application to particular combinations of elements, or steps, it should be understood that the scope of the disclosure of the present application also includes any single novel element, or step, or any novel combination of elements, or steps, disclosed herein, either explicitly or implicitly, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived there from.

We claim:

1. A device for determining an optimal snubber resistor value for an inductor discharging circuit to enable nearly constant rate of change of discharge current through said inductor discharging circuit, said device comprising:
an inductance-measuring element for measuring an intended output inductor's inductance;
a capacitance-measuring element for measuring an intended output capacitor's capacitance;
a first processing element that determines and sets as a root-determined-value the positive square root of the quotient of the inductance obtained by the inductance-measuring element divided by the capacitance obtained by the capacitance-measuring element, thereby establishing the root-determined value as a first real-world constraint for the snubber resistance value and an optimal and goal resistance value;
at least one resistance-measuring element, to which each and all of an intended output inductor and its connected and intended output wiring and any connector(s) are connected, by which their respective resistances are measured, thereby obtaining an actual and measured resistance for each of the intended output inductor, its connected and intended output wiring and any connector(s);
a second processing element that receives from the resistance-measuring element the actual and measured resistance of each of the intended output inductor, its connected and intended output wiring and any connector(s), and by summing these resistances determines and sets as a sum-determined value an actual and total in-circuit resistance as a second real-world constraint for the snubber resistance value;
means for subtracting from the optimal and goal resistance value the actual and total in-circuit resistance, thereby determining an actual snubber resistor value for the inductor discharging circuit; and,
means for any of storing and displaying on a display element as a specific and actual design constraint the optimal actual snubber resistor value for the inductor discharging circuit.

2. A device as in claim 1, said device further comprising a separate resistance measuring element for each of the intended output inductor, its connected and intended output wiring and any connector(s), with each separate resistance measuring element connected to and feeding its measured values to the second processing element.

3. A device as in claim 1, wherein the first processing element, second processing element, and means for subtracting from the optimal and goal resistance value the actual and total in-circuit resistance, further comprise:
a single arithmetic processing element capable of each of addition, division, root extraction, and subtraction;
memory for the operand values;
memory for the result value;
control and timing process circuitry; and,
connections to the input and output feeds for the measurement, constraint, and result values effected by the operation of the arithmetic processing element.

4. A device as in claim 1, further comprising for each measuring element, an output element capable of displaying both the value measured by that element and the unit of measurement for the value measured by that element.

5. A device as in claim 4, further comprising as error-detecting and correcting means to protect against common, and cross-cultural, circuit-design errors:
means for a user to enter for any value which is measured its mensuration unit;
means for the mensuration unit of each operand to be comparatively checked;
means for cross-checking, for a differentiated pair of mensuration units, and obtaining from a standardized table of comparatives an equalizing transformation that is effected on at least one operand to standardize both mensuration units to a common and standardized unit, after which the calculation is allowed to proceed using the replacement common and standardized mensuration unit for all operands;
or, when no standardization can be obtained, displaying instead of the result of the calculation a specific error message identifying the differentiation between mensuration units, and halting further processing.

6. A method for determining a snubber resistor value for an inductor discharging circuit to enable nearly constant rate of change of discharge current, said method comprising:
measuring the output power capacitor's capacitance;
measuring the output inductor's inductance;
measuring the output inductor's resistance; and,
measuring the output wiring and connector(s) combined resistance which comprise the in-circuit resistance;
establishing the optimal snubber resistor value by taking the positive square root of the quotient of the inductance divided by the capacitance;
also totaling the output inductor's, output wiring's and connector(s)'s resistances, thus establishing the in-circuit resistance; and,
finally subtracting the in-circuit resistance optimal snubber resistor value, to determine the actual, optimal snubber resistance value.

7. A method as in claim 6 further comprising allowing the entry of a predetermined actual, and optimal snubber resistor value, from which a selected specific value for another, user-selected element of the inductive discharge circuit may be identified through solving for that user-selected element's value as an unknown, after measuring all remaining element's values.

8. A method as in claim 7 further comprising the use of a linear display graph to show as a curve the respective pairing of unknown values which will solve, for any two elements of the inductive discharge circuit, the optimal effective value at each possible pairing of result values, over the range(s) of undetermined values for the elements involved.

9. A method as in claim 7 further comprising, when the snubber resistor value is already fixed:
measuring total circuit resistance;
adding the snubber resistor value to the total calculated resistances to establish the optimal snubber resistor value;
calculating respective paired values of inductance and capacitance which will, for their calculated positive square root and division, result in the optimal snubber resistor value; and,
displaying, for any selected value of either inductance or capacitance on the curve, the matching other value.

10. A process for producing as a product a snubber resistor having an actual, optimal resistor value for an inductor discharging circuit to enable nearly constant rate of change of discharge current, said process comprising:
measuring the output power capacitor's capacitance;
measuring the output inductor's inductance;
measuring the output inductor's resistance; and,
measuring the output wiring and connector(s) combined resistance which comprise the in-circuit resistance;
establishing the optimal snubber resistor value by taking the positive square root of the quotient of the inductance divided by the capacitance;
also totaling the output inductor's, output wiring and connector resistances, thus establishing the in-circuit resistance; and,
finally subtracting the in-circuit resistance optimal snubber resistor value, to determine the actual, optimal snubber resistance value; and,
making a snubber resistor having as its actual resistor value that optimal snubber resistance value.
